(19) United States
(12) Patent Application Publication
(10) Pub. No.: US 2024/0429858 A1
(43) Pub. Date: Dec. 26, 2024

(54) SOLAR CHARGER FOR CYLINDER CELLS

(71) Applicant: ShenZhen YangZhe New Energy Technology Co., Ltd, Shenzhen (CN)

(72) Inventor: Qiongbin XIE, Shenzhen (CN)

(73) Assignee: ShenZhen YangZhe New Energy Technology Co., Ltd, Shenzhen (CN)

(21) Appl. No.: 18/353,832

(22) Filed: Jul. 17, 2023

(30) Foreign Application Priority Data
Jun. 21, 2023 (CN) 2023215935181

(51) Int. Cl. H02S 40/38; H01L 31/0232; H02S 30/10

(52) U.S. Cl. CPC H02S 40/38; H01L 31/0232; H02S 30/10

(57) ABSTRACT

A solar charger for cylinder cells is disclosed, including a solar panel, a cell compartment and a light angle detection module. The light angle detection module is provided with a transparent mask and a dial, a center of the transparent mask is provided with an opaque shading point, and a top surface of the dial is provided with a crosshair centered along a central axis of the shading point. When a projection of the shading point in the sun is just right on the crosshair, the solar panel can obtain a best photovoltaic power generation effect.

### CROSS-REFERENCE TO RELATED APPLICATIONS

The application claims priority to Chinese patent application No. 2023215935181, filed on Jun. 21, 2023, the entire contents of which are incorporated herein by reference.

### TECHNICAL FIELD

The invention relates to the technical field of photovoltaic technology, in particular, to a solar charger for cylinder cells.

### BACKGROUND

In the prior art, cylinder cells are used in a wide range of scenarios, such as children's toys, CCD cameras, KTV microphones, remote controls, wireless keyboards and mice, and shavers. At present, the cylinder cells widely used in the market are mostly Ni-MH cells and lithium cells, and the main specifications are mainly AA cells and AAA cells.

For the device, the endurance of the cell is very important. In the prior art, most of the supporting chargers are connected to the utility power for charging, or externally connected to a mobile power supply for charging. However, for people who are outdoors for a long time, it is difficult to find utility power. Further, the mobile power supply has a limited capacity: once it is exhausted, it is still necessary to find a utility power for recharging, or to reserve multiple mobile power supplies at one time. Obviously, for long-term outdoor use, a charging solution that is not restricted by the utility power is required, and solar photovoltaic technology is the most environmentally friendly and economical design direction.

Therefore, how to use solar photovoltaic technology to better realize a solar charger for cylinder cells is a positive technical iterative research direction.

### SUMMARY

The invention aims at providing a solar charger for cylinder cells, with technical solutions as below.

A solar charger for cylinder cells is disclosed, including a solar panel, a cell compartment and a light angle detection module; the cell compartment is arranged on a back surface of the solar panel, and the cell compartment is provided with a control circuit board connected to the solar panel to form a circuit: the cell compartment is provided with a charging slot for receiving a cylinder cell, and the charging slot is provided with an electrode for matching the cylinder cell: the electrode is connected to the control circuit board: the light angle detection module is arranged on a front surface of the solar panel; and is provided with a transparent mask and a dial that are arranged up and down along a normal direction of the solar panel: a center of the transparent mask is provided with an opaque shading point, and a top surface of the dial is provided with a crosshair centered along a central axis of the shading point.

In an improved solution, the crosshair is of a cross-shaped structure.

In an improved solution, a panel arranged on the front surface of the solar panel is further included, wherein the panel is equipped with a plurality of indicators controlled by the control circuit board to emit light.

Preferably, the light angle detection module is mounted on the panel.

Preferably, the indicator is a light guide embedded in the panel, the control circuit board is equipped with a number of lamp beads that match the indicators one by one, and the indicator constitutes and only constitutes light transmission for the matched lamp beads.

In an improved solution, a bracket assembly arranged on the back surface of the solar panel is further included, wherein the bracket assembly includes a damping shaft and a rotating arm, one end of the rotating arm is rotated and matched with the solar panel through the damping shaft, and the damping shaft provides rotational damping for the rotating arm.

Preferably, the damping shaft includes a spring sleeve fixedly mounted in the cell compartment and a cylinder spring coaxially arranged in the spring sleeve, a tail end of the spring sleeve is open, a head end of the spring sleeve is closed and formed with a first toothed disc on an outer end surface, and a center of the first toothed disc is provided with a round hole: the damping shaft further includes a rotating shaft coaxially passing through the cylinder spring, a head end of the rotating shaft passes through the head end of the spring sleeve through the round hole, the rotating shaft forms an axial movable fit and a rotational fit in the round hole, and a tail end on the rotating shaft grows out of the tail end of the spring sleeve and is mounted with a circlip abutting against the tail end of the cylinder spring, so that the head end of the cylinder spring abuts against an inner end surface of the first toothed disc; the damping shaft further includes a second toothed disc engaged with the first toothed disc, and the second toothed disc is coaxially mounted on the rotating shaft; the head end and the tail end of the rotating shaft are respectively connected with the rotating arm, and the rotating arm, the rotating shaft and the second toothed disc form a relatively static fit.

In an improved solution, the cell compartment is provided with an external power inlet connected to the control circuit board.

In an improved solution, the cell compartment is provided with a charging output port connected to the control circuit board.

Compared with the prior art, the invention has the following beneficial effects: the solar charger for cylinder cells is implemented using solar photovoltaic technology:

when the sun shines on the solar panel, the shading point on the transparent mask will cast a projection on the dial; when the projection of the shading point in the sun is exactly on the crosshair, it means that the sunlight is perpendicular to the solar panel, so that a tilt angle at which the solar panel is placed may be adjusted so that the sunlight is perpendicular to the solar panel, i.e., causing the solar panel to obtain the best photovoltaic power generation effect.

The invention will be further described in combination with drawings and the specific embodiments of the specification.

### BRIEF DESCRIPTION OF DRAWINGS

FIG. 1 is a structural diagram of the invention.

FIG. 2 is an exploded structural diagram of the invention.

FIG. 3 is a structural diagram of a light angle detection module in the invention.

FIG. 4 is a diagram of a working status of the invention.

FIG. 5 is a diagram showing the assembly of the damping shaft in the invention.

### DETAILED DESCRIPTION OF THE EMBODIMENTS

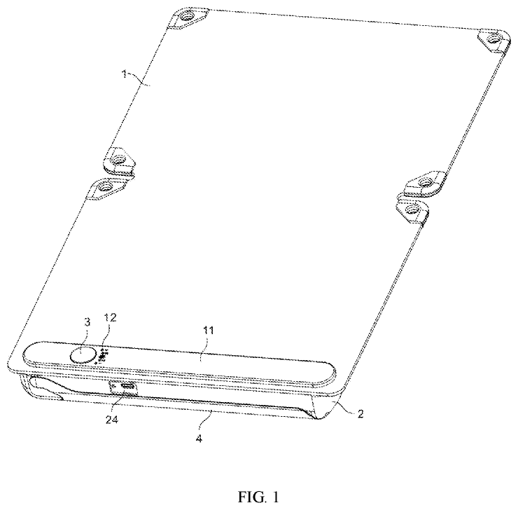

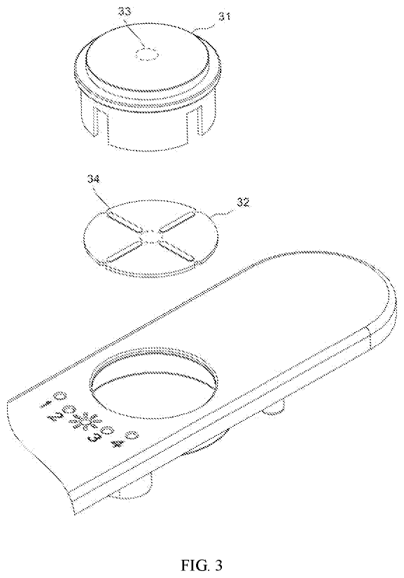

As shown in FIGS. 1 to 3, in an embodiment, the invention provides a solar charger for cylinder cells, which includes a solar panel 1, a cell compartment 2 and a light angle detection module 3: the cell compartment 2 is arranged on a back surface of the solar panel 1, and the cell compartment 2 is provided with a control circuit board 21 connected to the solar panel 1 to form a circuit; the cell compartment 2 is provided with a charging slot 22 for receiving a cylinder cell, and the charging slot 22 is provided with an electrode 23 for matching the cylinder cell; the electrode 23 is connected to the control circuit board 21; the light angle detection module 3 is arranged on a front surface of the solar panel 1, and is provided with a transparent mask 31 and a dial 32 that are arranged up and down along a normal direction of the solar panel 1; a center of the transparent mask 31 is provided with an opaque shading point 33, and a top surface of the dial 32 is provided with a crosshair 34 centered along a central axis of the shading point 33.

The embodiment described above realizes the solar charger for cylinder cells using solar photovoltaic technology. Typically, in the above embodiment, a solar panel of ETFE process with 12 Wh power is selected to charge the cylinder cell with 4 charging slots, and the solar panel reduces voltages of 15V/2 A and divides into 4 groups of 1.5V/300 MA to charge 4 cylinder cells.

And, in the above embodiment, when the sun shines on the solar panel 1, the shading point 33 on the transparent mask 31 will cast a projection on the dial 32; when the projection of the shading point 33 in the sun is exactly on the crosshair 34, it means that the sunlight is perpendicular to the solar panel 1, so that a tilt angle at which the solar panel 1 is placed may be adjusted so that the sunlight is perpendicular to the solar panel 1, i.e., causing the solar panel 1 to obtain the best photovoltaic power generation effect. Further, the crosshair 34 is of a cross-shaped structure.

Further, a panel 11 arranged on the front surface of the solar panel 1 is further included, wherein the panel 11 is equipped with a plurality of indicators 12 controlled by the control circuit board 21 to emit light, and 4 groups of red and blue lights may be used for 4 groups of Ni-MH cells to indicate the charging and full charging status.

Preferably, the light angle detection module 3 is mounted on the panel 11.

Preferably, the indicator 12 is a light guide embedded in the panel 11, the control circuit board 21 is equipped with a number of lamp beads that match the indicators 12 one by one, and the indicator 12 constitutes and only constitutes light transmission for the matched lamp beads. Specifically, it is a conventional arrangement to use a light guide as an illuminating indicator, which is not repeated in description in the invention.

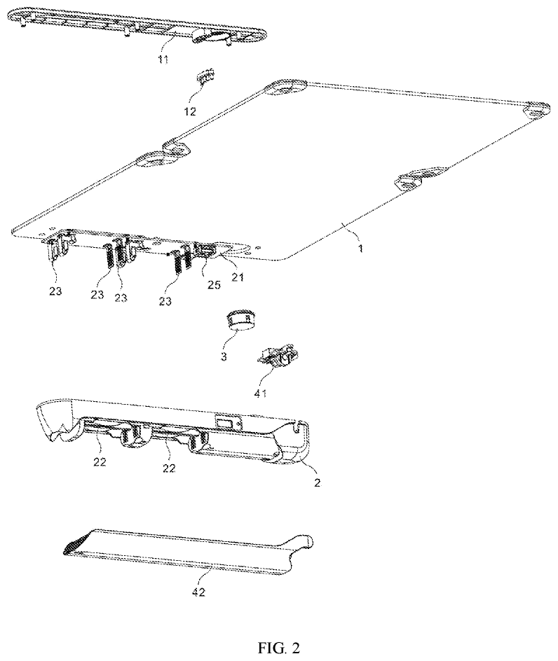

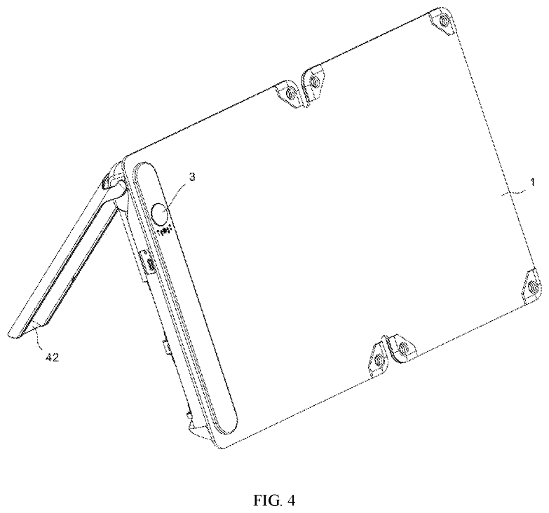

In another solution of the embodiment, as shown in FIGS. 2 and 4, a bracket assembly 4 arranged on the back surface of the solar panel 1 is further included, wherein the bracket assembly 4 includes a damping shaft 41 and a rotating arm 42, one end of the rotating arm 42 is rotated and matched with the solar panel 1 through the damping shaft 41, and the damping shaft 41 provides rotational damping for the rotating arm 42.

Since the damping rotating shaft 41 provides rotational damping for the rotating arm 42, the bracket assembly 4 of the invention realizes extremely easy-to-operate rotating storage. In particular, by adjusting different angles of the rotating arm 42 to realize the angle at which the sunlight irradiates on the surface of the solar panel 1, so as to achieve the best effect of solar power generation.

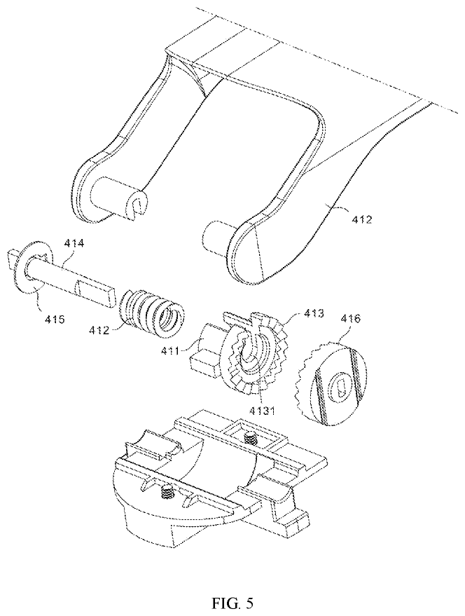

Preferably, as shown in FIG. 5, the damping shaft 41 includes a spring sleeve 411 fixedly mounted in the cell compartment 2 and a cylinder spring 412 coaxially arranged in the spring sleeve 411, a tail end of the spring sleeve 411 is open, a head end of the spring sleeve 411 is closed and formed with a first toothed disc 413 on an outer end surface, and a center of the first toothed disc 413 is provided with a round hole 4131; the damping shaft 41 further includes a rotating shaft 414 coaxially passing through the cylinder spring 412, a head end of the rotating shaft 414 passes through the head end of the spring sleeve 411 through the round hole 4131, the rotating shaft 414 forms an axial movable fit and a rotational fit in the round hole 4131, and a tail end on the rotating shaft 414 grows out of the tail end of the spring sleeve 411 and is mounted with a circlip 415 abutting against the tail end of the cylinder spring 412, so that the head end of the cylinder spring 412 abuts against an inner end surface of the first toothed disc 413; the damping shaft 41 further includes a second toothed disc 416 engaged with the first toothed disc 413, and the second toothed disc 416 is coaxially mounted on the rotating shaft 414; the head end and the tail end of the rotating shaft 414 are respectively connected with the rotating arm 42, and the rotating arm 42, the rotating shaft 414 and the second toothed disc 416 form a relatively static fit.

It can be understood that when the rotating arm 42 is rotated, the rotating arm 42 drives the rotating shaft 414 and the second toothed disc 416 to rotate, so that the first toothed disc 413 is extruded to retreat axially by a rotating torque; when the first toothed disc 413 and the second toothed disc 416 rotate relative to each other until the next pair of teeth are engaged, a new angle has been formed by adjusting between the rotating arm 42 and the solar panel 1.

In an improved solution, the cell compartment 2 is provided with an external power inlet 24 connected to the control circuit board 21, and direct connection to the utility power through the external power inlet may be served as an external power supply to replace solar energy for charging. Optionally, the external power inlet is a TYPE-C interface.

In an improved solution, the cell compartment 2 is provided with a charging output port 25 connected to the control circuit board 21, and 5V/2 A is output through the charging output port for directly charging mobile phones and other digital devices. Optionally, the charging output port is a USB-A port.

For those skilled in the art, the protection scope of the invention is not limited to the details of the exemplary embodiments described above. Without departing from the spirit or essential characteristics of the invention, all changes within the equivalent meaning and protection scope made by those skilled in the art based on the requirements of the invention shall be included in the invention.

What is claimed is:

1. A solar charger for cylinder cells,
comprising a solar panel, a cell compartment and a light angle detection module;
wherein the cell compartment is arranged on a back surface of the solar panel, and the cell compartment is provided with a control circuit board connected to the solar panel to form a circuit; the cell compartment is provided with a charging slot for receiving a cylinder cell, and the charging slot is provided with an electrode for matching the cylinder cell: the electrode is connected to the control circuit board;
the light angle detection module is arranged on a front surface of the solar panel; and is provided with a transparent mask and a dial that are arranged up and down along a normal direction of the solar panel: a center of the transparent mask is provided with an opaque shading point, and a top surface of the dial is provided with a crosshair centered along a central axis of the shading point.

2. The solar charger for cylinder cells according to claim 1, wherein the crosshair is of a cross-shaped structure.

3. The solar charger for cylinder cells according to claim 1, further comprising a panel arranged on the front surface of the solar panel, wherein the panel is equipped with a plurality of indicators controlled by the control circuit board to emit light.

4. The solar charger for cylinder cells according to claim 3, wherein the light angle detection module is mounted on the panel.

5. The solar charger for cylinder cells according to claim 3, wherein the indicator is a light guide embedded in the panel, the control circuit board is equipped with a number of lamp beads that match the indicators one by one, and the indicator constitutes and only constitutes light transmission for the matched lamp beads.

6. The solar charger for cylinder cells according to claim 1, further comprising a bracket assembly arranged on the back surface of the solar panel, wherein the bracket assembly comprises a damping shaft and a rotating arm, one end of the rotating arm is rotated and matched with the solar panel through the damping shaft, and the damping shaft provides rotational damping for the rotating arm.

7. The solar charger for cylinder cells according to claim 6, wherein the damping shaft comprises a spring sleeve fixedly mounted in the cell compartment and a cylinder spring coaxially arranged in the spring sleeve, a tail end of the spring sleeve is open, a head end of the spring sleeve is closed and formed with a first toothed disc on an outer end surface, and a center of the first toothed disc is provided with a round hole; the damping shaft further comprises a rotating shaft coaxially passing through the cylinder spring, a head end of the rotating shaft passes through the head end of the spring sleeve through the round hole, the rotating shaft forms an axial movable fit and a rotational fit in the round hole, and a tail end on the rotating shaft grows out of the tail end of the spring sleeve and is mounted with a circlip abutting against the tail end of the cylinder spring, so that the head end of the cylinder spring abuts against an inner end surface of the first toothed disc: the damping shaft further comprises a second toothed disc engaged with the first toothed disc, and the second toothed disc is coaxially mounted on the rotating shaft; the head end and the tail end of the rotating shaft are respectively connected with the rotating arm, and the rotating arm, the rotating shaft and the second toothed disc form a relatively static fit.

8. The solar charger for cylinder cells according to claim 1, wherein the cell compartment is provided with an external power inlet connected to the control circuit board.

9. The solar charger for cylinder cells according to claim 1, wherein the cell compartment is provided with a charging output port connected to the control circuit board.
